(19) United States
(12) Patent Application Publication
(10) Pub. No.: US 2025/0393326 A1
(43) Pub. Date: Dec. 25, 2025

(54) ELECTRONIC DEVICE

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 19/241,989

(22) Filed: Jun. 18, 2025

(30) Foreign Application Priority Data
Jun. 21, 2024 (FR) FR2406707

(51) Int. Cl. H10F 39/00; B82Y 20/00; G02B 5/28; H10F 39/18

(52) U.S. Cl. CPC H10F 39/8067; G02B 5/281; H10F 39/1825; H10F 39/8053; B82Y 20/00

(57) ABSTRACT

An imaging device includes a stack formed by a first silicon photodiode and a second photodiode based on quantum dots. The first silicon photodiode is arranged between a side of the stack configured to receive incident light and the second photodiode. The incident light includes infrared wavelengths and visible wavelengths. A filter positioned between the first silicon photodiode and the second photodiode reflects visible wavelengths back to the first silicon photodiode and passes infrared wavelengths through to the second photodiode.

### PRIORITY CLAIM

This application claims the priority benefit of French Application for Patent No. FR2406707, filed on Jun. 21, 2024, the content of which is hereby incorporated by reference in its entirety to the maximum extent allowable by law.

### TECHNICAL FIELD

The present disclosure generally concerns electronic devices and, more specifically, optoelectronic devices comprising photodiodes, as well as associated methods for manufacturing optoelectronic devices comprising photodiodes.

### BACKGROUND

A photodiode is a semiconductor component having the ability to capture a radiation in the optical field and to transform it into an electrical signal.

In a common type of photodiodes, the space charge region is located in a semiconductor material, generally silicon. However, silicon is not very reactive at near-infrared (NIR) and short-wave infrared (SWIR) wavelengths.

There exists a need to provide devices sensitive both to wavelengths in the visible range and to infrared wavelengths.

There is a need to overcome all or part of the disadvantages of known devices.

### SUMMARY

An embodiment provides a device comprising a stack formed at least of: a first silicon photodiode; and a second photodiode based on quantum dots; wherein the first silicon photodiode is arranged between a side of the stack configured to receive incident light and the second photodiode.

An embodiment provides a method of manufacturing a device comprising: forming a first silicon photodiode; then forming of a second photodiode based on quantum dots so as to form a stack with the first silicon photodiode; wherein the first silicon photodiode is arranged between a side of the stack configured to receive incident light and the second photodiode.

In an embodiment, the device comprises a first filter interposed between the first silicon photodiode and the second photodiode, said first filter configured to let through infrared wavelengths and reflect visible wavelengths.

In an embodiment, the device comprises at least one second filter, of a first color of the visible range, configured to only let through wavelengths of said first color and infrared wavelengths.

In an embodiment, the first silicon photodiode is sensitive only to wavelengths of the visible range.

In an embodiment, the second photodiode is sensitive mainly to infrared.

In an embodiment, said second photodiode comprises a first layer comprising the quantum dots and doped with a first conductivity type, and a second layer configured to conduct holes originating from the first layer.

In an embodiment, said second photodiode comprises a third layer comprising quantum dots and doped with a second conductivity type, and arranged between said first layer and said second layer.

In an embodiment, the device comprises an interconnection level comprising conductive interconnects arranged between the first silicon photodiode and the second filter; wherein a first conductive via, insulated from the first silicon photodiode, couples, through the first silicon photodiode and through the first filter, the second photodiode to the interconnection level.

In an embodiment, the second photodiode comprises a fourth layer configured to conduct electrons and block the conduction of holes, and to couple the first layer to the first via.

In an embodiment, said first via comprises a first portion made of polysilicon and a second portion made of a metallic material, said second portion being arranged between the first portion and the fourth layer.

In an embodiment, said metallic material has a work function configured to facilitate electron extraction.

In an embodiment, said first via is made of silicon and with the first or the second conductivity type, said first via being in contact with said first layer.

In an embodiment, the first silicon photodiode comprises a first region doped according to the first conductivity type, a second region doped according to a second conductivity type, and a third region, formed in the first region and doped according to the first conductivity type with a dopant concentration higher than that of the first region; the second region being arranged between the first filter and the first region; the third region being arranged in contact with the interconnection level.

In an embodiment, said first filter is an interference filter comprising a periodic alternation of an SiON layer of approximately 125 nm thickness and of an amorphous silicon layer of approximately 50 nm thickness.

In an embodiment, the device comprises: a second stack of a third silicon photodiode and of a fourth photodiode based on quantum dots, the third silicon photodiode being arranged between a side of the second stack configured to receive incident light and the fourth photodiode; a third interference filter interposed between the third silicon photodiode and the fourth photodiode, and configured to let through infrared wavelengths and reflect wavelengths of the visible range; a fourth filter of a second color of the visible range different from the first color configured to only let through wavelengths of said second color and infrared wavelengths.

In an embodiment, the second and fourth filters are interference filters.

In an embodiment: the second filter only lets through wavelengths of said first color and infrared wavelengths to which the second photodiode is sensitive; and the fourth filter only lets through wavelengths of said second color and infrared wavelengths to which the fourth photodiode is sensitive.

In an embodiment, the first filter and the third filter let through different infrared wavelengths.

An embodiment provides a method of using the above-described device, comprising the acquisition of images in the visible range from said first silicon photodiode and in the infrared range from said second photodiode.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a simplified perspective view of an example of an electronic device;

FIG. 2 shows a cross-section view along a plane A-A of the electronic device of FIG. 1;

FIG. 3 shows a cross-section view along plane A-A of the electronic device of FIG. 1;

FIG. 4 shows a cross-section view along a plane B-B of FIG. 2;

FIG. 5a shows a graph of transmittance versus wavelength for the examples of FIGS. 1 to 3;

FIG. 5b shows a graph of absorbance versus wavelength for the examples of FIGS. 1 to 3;

FIG. 5c shows a graph of transmittance versus wavelength for the examples of FIGS. 1 to 3;

FIG. 5d shows a graph of absorbance versus wavelength for the examples of FIGS. 1 to 3;

FIG. 6 shows a cross-section view along plane A-A of FIG. 1;

FIG. 7 shows a cross-section view along plane A-A of FIG. 1;

FIG. 8a shows graphs of absorbance versus wavelength for the example of FIG. 7;

FIG. 8b shows graphs of transmittance versus wavelength for the example of FIG. 7;

FIG. 8c shows graphs of absorbance versus wavelength for the example of FIG. 7;

FIG. 9 shows an enlarged view of FIG. 2; and

FIG. 10 shows an enlarged view of FIG. 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

Light detection, for example multispectral both in the visible range and in the infrared range, can be envisaged by using a single channel or multiple channels with photodiodes all based on quantum dots. However, the detection level in the visible range is lower for quantum dots than in the infrared range, due to the generated dark currents.

The implementation of this or these channel(s), but with silicon instead of the quantum dots, is not efficient, since silicon is not sensitive to infrared, for example, at wavelengths beyond 1,100 nm.

It may be envisaged to use a semiconductor layer with no quantum dots for detection in the infrared range, for example with SiGe or also InGaAs, but it is extremely difficult to obtain these materials cheaply and satisfactorily from a silicon substrate. Further, SiGe has a fairly low detection level as compared with quantum dots.

Solutions of assemblies of a plurality of substrates may be envisaged, but they are expensive.

Finally, the integration of layers with quantum dots sensitive in near infrared, on a front side of a device, gives rise to an absorption of part of the visible radiation reaching this front side. The integration of layers with quantum dots sensitive in near infrared, on a back side of a device, but with a back-side illumination, also gives rise to an attenuation of the detectable visible light.

To overcome these disadvantages, the described embodiments provide a device comprising a stack formed of at least: a first silicon photodiode; and a second photodiode based on quantum dots; wherein the first silicon photodiode is arranged between a side of the stack configured to receive incident light and the second photodiode.

This enables to obtain both a high-performance visible light detection with a photodiode based on silicon, and a high-performance infrared detection with a photodiode based on quantum dots, and this, at limited costs.

This further enables to obtain a device which can both operate as a multispectral ambient light detector while integrating a proximity sensor operating at infrared wavelengths such as, for example, the 1,130 or 1,360-nm wavelengths.

In the text, the infrared range comprises, for example, short-wave infrared (SWIR) wavelengths. In other words, in the text, infrared comprises, for example, wavelengths greater than or equal to 1 μm, for example 1.1 μm, 1.130 μm, or also 1,360 nm. Near infrared (NIR), having wavelengths ranging between 780 and 1 μm, may also be considered in the following examples, for example by modifying the quantum dot size or nature.

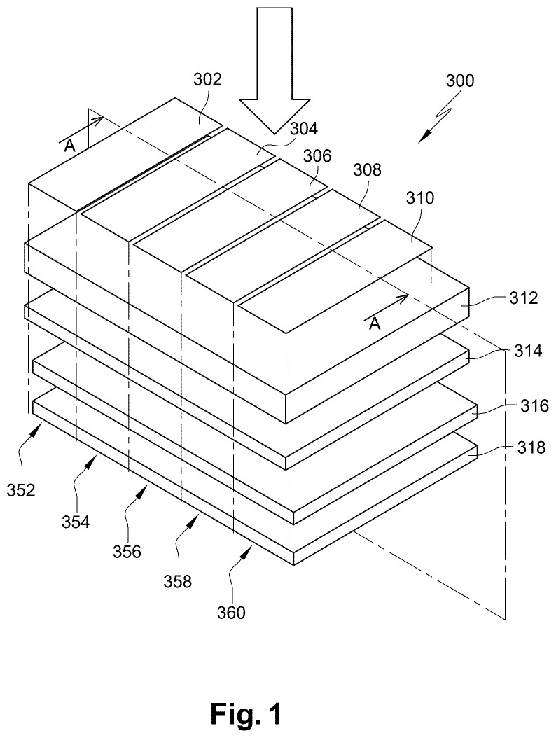

FIG. 1 shows a simplified perspective view of an example of an electronic device 300.

Electronic device 300 is, for example, an ambient light sensor for visible spectral analysis and at the same time a proximity sensor, specifically using the short-wave infrared spectrum.

In the shown example, a plurality of optical detection channels 352, 354, 356, 358, 360 are adjacent. An optical channel can be seen as a fairly large pixel.

In the shown example, each of these channels 352, 354, 356, 358, 360 comprises a first region or photodiode 312 made of a semiconductor material, such as silicon, and for example based on a single junction. Further, channels 352, 354, 356, 358, 360 comprise, for example, a second region or photodiode 316, arranged at least partly vertically in line with the first photodiode 312 so as to form a stack. Photodiode 316 is based on quantum dots.

In an example, each channel 352, 354, 356, 358, 360 is insulated (or separated) from the adjacent channel by an electrical and/or optical insulator and/or a trench. In another example, each channel is sufficiently wide not to require a separator or an insulator between adjacent channels.

Channels 352, 354, 356, 358, 360 also comprise, for example, an optical filter 314 or optical steering element 314. Filter 314 is configured to let through infrared wavelengths, in particular short-wave infrared wavelengths, towards the second photodiode 316 located underneath, and to redirect visible wavelengths towards the first photodiode 312. In other words, filter 314 is configured, for example, to deflect with a certain angle wavelengths of the visible domain which have passed through the first photodiode without being absorbed and to let through or deflect with another, very small, angle wavelengths of the infrared range. Thereby, infrared wavelengths are directed towards the second photodiode 316, while visible wavelengths are returned to the first photodiode 312.

In an example, optical filter 314 is a first interference filter 314, for example a distributed Bragg reflector, which is interposed between the first region 312 and the second region 316. In an example, the same first filter 314 is common to the different channels and is arranged over the entire horizontal extent of the channels. In another example, each channel has a different first filter, the filtering properties of which may be different. In this last example, the extent of the first filter 314 is limited to the horizontal extent of each channel, and the wavelengths let through by each first filter 314 may vary from one channel to another.

In another example, filter 314 is a meta surface. This meta surface comprises, for example, pillars or raised areas made of a material of a high optical (or refractive) index, for example above 2, for example of metal oxide, for example of TiO₂. In an example, these pillars are arranged in a matrix of lower optical index, for example a nitride, for example silicon nitride.

The layout and the shape of the pillars or of the raised areas of high optical index can be simulated to obtain the different deflections according to the desired wavelengths.

The use of an optimized distributed Bragg reflector allows the reflection of visible wavelengths towards the silicon photodiodes to ensure a maximum absorption of the photodiodes in the visible range. The distributed Bragg reflector is also used as a bandpass filter to let through a very large portion of the infrared spectrum through the photodiodes based on quantum dots. This approach is more optimal than the approach consisting of using materials sandwiched between two distributed Bragg reflectors, which results in an absorption peak defined by cavity effects. Indeed, this second approach creates a very pitted absorption highly sensitive to the angle of incidence of the light entering the system, to the detriment of the sensor operation.

Each channel 352, 354, 356, 358, 360 comprises, for example, a second filter 302, 304, 306, 308, 310 of a different color in the visible range, only letting through visible wavelengths of the respective color and wavelengths of the infrared domain. The second filter of each channel is arranged above the first photodiode 312 of the channel so that the incident light, symbolized by an arrow in the drawing, first passes through the second filter 302, 304, 306, 308, 310, then through the first diode 312, then through the first filter 314, and finally through the second photodiode 316.

In the shown example, a protective layer 318, such as a thick oxide, is arranged under photodiodes 316.

In an example, the first region 312 has a thickness of a few micrometers, for example 4 or 5 μm, filter 314 around 500 nm, and photodiodes 316 around 500 nm.

Filter 314 is configured to let through infrared wavelengths and to reflect wavelengths of the visible range.

In an example, filter 314 is formed of a stack repeated a plurality of times and formed of a layer of high refraction index and of a layer of lower refractive index. In an example, filter 314 is formed of a stack repeated a plurality of times and formed of an SiON layer having a thickness of approximately 125 nm and of an amorphous silicon layer having a thickness of approximately 50 nm. Such a filter lets through wavelengths of short-wave infrared, for example between 1,130 nm and 1,360 nm.

Filters 302, 304, 306, 308, 310 are, for example, formed with an interference filter, for example a distributed Bragg reflector, or with meta-surfaces formed of periodic arrangements of pillars having different optical indices. In an example, each of filters 302, 304, 306, 308, 310, is configured to only let through wavelengths centered around a given visible wavelength, different for each second filter, as well as infrared. In another example, each of filters 302, 304, 306, 308, 310, is configured to only let through lengths centered around a given visible wavelength, different for each filter 302, 304, 306, 308, 310, as well as lengths centered around a given infrared wavelength, for example 1,130 or 1,360 nm and which may advantageously correspond to the wavelength of maximum absorbance of the quantum dots of the associated photodiode 316. For example, filter 302 lets through, in the visible range, blue color wavelengths only, filter 304 green color wavelengths only, filter 306 yellow color wavelengths only, filter 308 orange color wavelengths only, and filter 310 red color wavelengths only. In other words, the wavelengths originating from a filter of a given color are, for example, by more than 50%, preferably by more than 80%, and even more preferably by more than 90%, within the spectrum associated with this color.

In another example, the device comprises a single one of filters 302, 304, 306, 308, 310, or only two filters of different color, or three filters which may or not be of different colors.

In the text, the green color comprises wavelengths approximately in the range from 520 to 565 nm, the red color comprises wavelengths approximately in the range from 625 to 740 nm, and the blue color comprises wavelengths approximately in the range from 450 to 500 nm. Other filters associated with other visible colors are also possible, such as yellow-, orange-, cyan-, indigo-, or violet-colored filters.

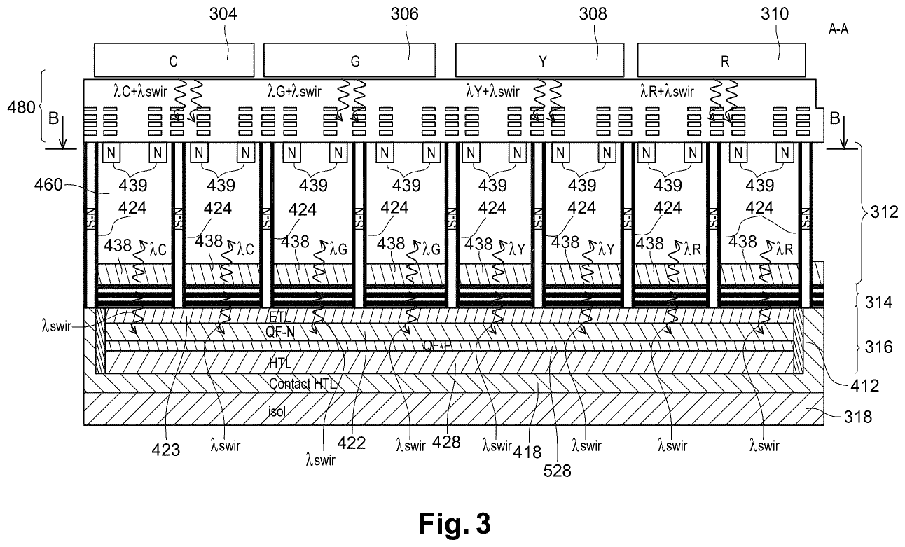

From a manufacturing point of view, in an example, photodiodes 312 are first formed with a backside technology, by epitaxy, in a silicon substrate. An interface oriented to receive light is, for example, then passivated. This is followed by the forming of the first filter 314. Then, through the silicon and the first filter, vias are formed by ion implantation of the first conductivity type, or with polysilicon, in deep trench isolation (DTI) trenches. These vias connect the second photodiode 316 to an interconnection network, not shown in FIG. 3, arranged between the second filter 302, 304, 306, 308, 310 and the first photodiode 312. Photodiode 316 is then formed in planar fashion with, for example, one or a plurality of layers of quantum dots in the form of colloids, for example by spin coating or by ink jet printing. The second photodiode 316 is then protected for example with a thick oxide layer 318. The substrate is then turned over and the second filters 302, 304, 306, 308, 310 are formed.

A quantum dot or semiconductor nanoparticle is a nanoscopic material structure which generates electron-hole pairs in the presence of the incidence of photons on the nanoscopic material structure.

A quantum dot comprises a semiconductor core. A quantum dot may also comprise a shell, preferably made of a semiconductor material, surrounding the core to protect and passivate the core. A quantum dot further comprises ligands, organic aliphatic compounds, metal-organic or inorganic molecules which extend from the shell and passivate, protect, and functionalize the semiconductor surface.

The composition of a quantum dot can be selected from among the following materials. For example, the core is made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAlP, InGaAlP, InZnS, InZnSe, InZnSeS, HgTe, HgSe, HgSeTe, Ge, Si. The shell is, for example, made of made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAlP, InGaAlP, InZnS, InZnSe, InZnSeS, HgTe, HgSe, HgSeTe, Ge, Si.

Preferably, all the core dimensions are smaller than 20 nm, for example in the range from 2 to 15 nm. In particular, the diameter of each quantum dot is preferably in the range from 2 to 15 nm. By diameter, there is meant the diameter of the smallest sphere within which the quantum dot can be inscribed.

It is possible to select a size and a dimension of quantum dots capable of absorbing, with a significant absorption, any wavelength in a wide range of wavelengths. For example, it is possible to find a size and a dimension of quantum dots having an operating wavelength greater than 1 μm, for example in the range from 1 μm to 3 μm, which includes near infrared and short-wave infrared. For example, photodiode 316 comprises quantum dots made of InAs, of PbS, of HgTe, or of PbSe, with a radius smaller than 10 nm, for example, to obtain an excitonic absorption peak in short-wave infrared, for example 1,130 nm or 1,360 nm.

The incident light formed of visible and infrared wavelengths is thus first filtered by filters 302, 304, 306, 308, 310 and then passes through the first photodiodes 312. Only infrared and a very small amount of visible light pass through the first photodiodes 312. The first filter 314 then only allows the propagation of infrared, for example short-wave infrared, to the second photodiode 316. The second photodiode 316 can thus be used to form a proximity sensor, since infrared, particularly short-wave infrared, is not absorbed by the other elements in the stack. This proximity sensor is, for example, obtained by coupling the second photodiode, for example using the interconnection layer not shown in FIG. 3, with a detection circuit not shown of device 300.

FIG. 1 shows a plane A-A running transversely through the thickness of device 300.

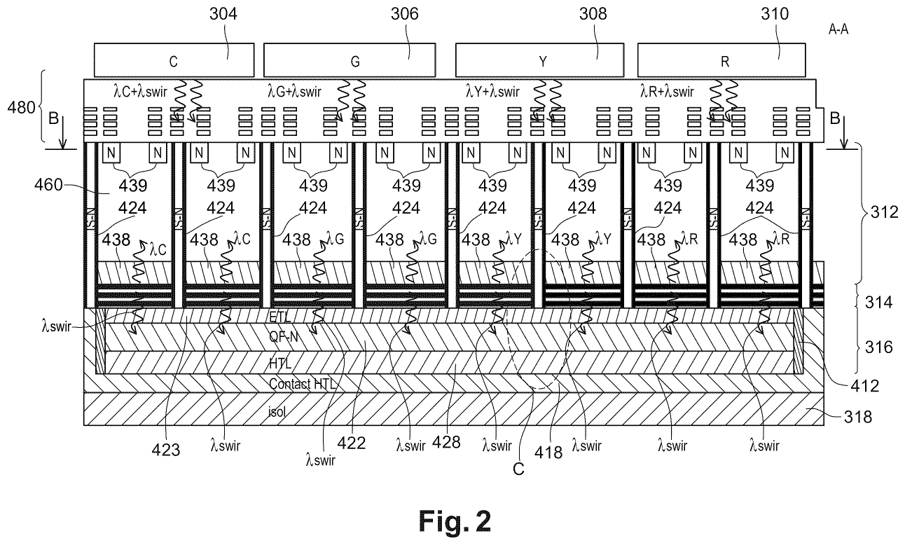

FIG. 2 shows a cross-section view along plane A-A of an example of electronic device 300.

In the example of FIG. 2, only filters 304, 306, 308 and 310 are shown for clarity.

In the shown example, a layer 480, otherwise known as an interconnection level, comprising interconnection levels, is interposed between filters 304, 306, 308, 310 and photodiode(s) 312. Layer 480 comprises, for example, one or a plurality of levels of metal lines coupled together by vertical metal vias. Layer 480 is coupled, preferably connected, to photodiodes 312 and 316.

In the shown example, photodiode(s) 312 comprises a first region 460 doped according to the first conductivity type, for example N. Photodiode 312 further comprises a second region 438 doped according to a second conductivity type, for example P, with, for example, a higher dopant concentration than the first region 460. In this example, photodiode 312 comprises a third region 439, formed in the first region 460 and doped according to the first conductivity type with a higher dopant concentration than the first region 460. In the shown example, region 439 is, for example, formed by one or a plurality of wells arranged within first region 460 and with one side in contact with interconnection level 480. Region 438 enables to combine the holes generated in photodiode 312.

In an example, a plurality of photodiodes 312 can be formed in adjacent fashion, for example separated by trenches or an insulator, so as to form a photodiode 312 vertically in line with each filter 304, 306, 308, 310 to form a multispectral visible light sensor.

In another example, a single photodiode 312 is formed and extends under all filters 304, 306, 308, 310. In this case, the respective connections of the third regions to interconnection level 480 may enable to define a level of the respective visible light received vertically in line with each of filters 304, 306, 308, 310, or the general level of the visible light received vertically in line with all filters 304, 306, 308, 310.

In the shown example, a same filter 314 is arranged vertically in line with the entire surface of filters 304, 306, 308, 310 and is interposed between the second region 438 of photodiode(s) 312 and photodiode(s) 316. Filter 314 reflects the visible radiation which has not been absorbed by the respective first photodiode 312 (λC, λG, λY, λR) and lets through infrared radiation, for example short-wave infrared radiation (λswir).

In the shown example, filter 314 is in contact with an electron transfer layer (ETL) 423, configured to conduct electrons and to block the conduction of holes in photodiode 316. In an example, layer 423 is made of ZnO, or of TiO₂, or of AZO. In an example, photodiode 316 also comprises a layer 422 (QF-N) with quantum dots which is in contact with layer 423. Layer 422 comprises quantum dots for example sensitive to wavelengths centered on 1.130 μm or 1.360 μm. In an example, layer 422 is doped with the first conductivity type, for example N. In the shown example, photodiode 316 further comprises a hole transfer layer (HTL) 428 which is configured to conduct holes originating from layer 422. This layer 428 is, for example, made of Mox, NiOx, for example P doped.

In an example, one or a plurality of conductive vias 424, insulated from photodiode 312, couple, preferably connect, through photodiode 312 and through filter 316, layer 423 to interconnection level 480. Certain vias 424, such as the outermost vias in FIG. 2, are coupled, preferably connected, to a layer 418 (HTL contact) which is arranged in contact with layer 428. Layer 418 enables to form a low-resistance contact for draining off the holes of photodiode 316. At these outer vias 424, layer 418 rises to connect to these outermost vias in FIG. 2. The layer is for example insulated from layers 423 and 422 by a layer 412.

In an example, layer 423 forms, for example, an electrode common to photodiode 312 and to photodiode 316, region 439 forms, for example, an electrode of photodiode 312, and layer 418 forms another electrode of photodiode 316.

In an example, a plurality of photodiodes 316 may be formed in adjacent fashion, for example separated by trenches or an insulator, so as to form a photodiode 316 vertically in line with each filter 304, 306, 308, 310 to form a proximity sensor for example provided with a plurality of pixels.

In an example, device 300 is used for white balance (PPG/ECG).

In another example, a single photodiode 316 is formed and extends under all filters 304, 306, 308, 310. In this case, via(s) 424 and their respective connection to interconnection level 480 may enable to define an infrared level received vertically in line with each of filters 304, 306, 308, 310, or the general infrared level received vertically in line with all filters 304, 306, 308, 310.

An enlarged view C of the contact area between one of vias 424 and layer 423 is shown in FIGS. 11 and 12.

In FIG. 2 is shown a plane B-B horizontally crossing device 300 at the level of regions 439.

FIG. 3 shows a cross-section view along plane A-A of an example of an electronic device 300 according to another embodiment.

The example in FIG. 3 is similar to that of FIG. 2, except that photodiode 316 further comprises, optionally, a layer 528 (QF-P) containing quantum dots and doped according to the second conductivity mode, for example P. Layer 528 is, for example, arranged between layers 422 and 428. Layer 528 forms, for example, a junction with layer 422.

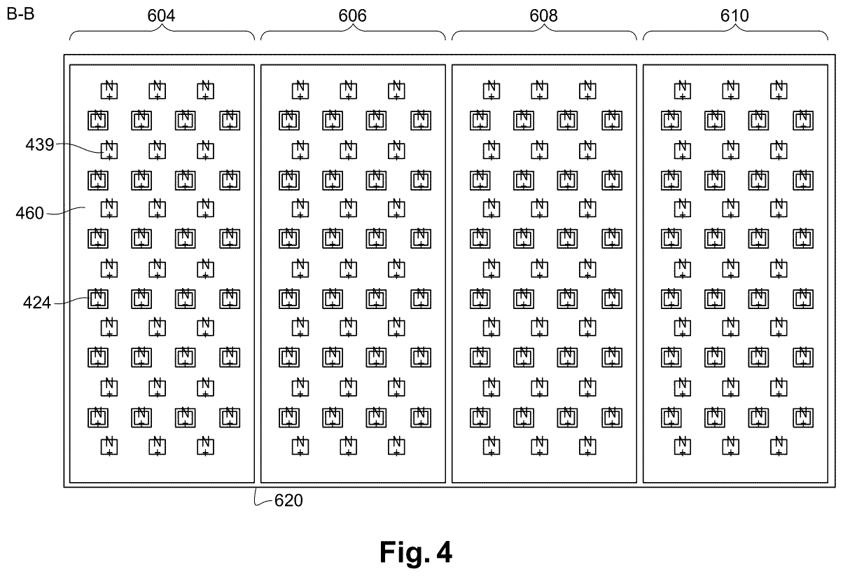

FIG. 4 shows a cross-section view along plane B-B of the example of FIG. 2.

In the shown example, device 300 comprises a plurality of channels 604, 606, 608, 610, each dedicated to a color and which are shown in cross-section in top view. Each channel extends horizontally along the entire horizontal footprint of the corresponding filter 304, 306, 308, 310. In an example, each channel extends horizontally along part of the horizontal footprint of the corresponding filter 304, 306, 308, 310. Each channel comprises an alternation of vias 424 and of regions 439 arranged in staggered fashion and along a plurality of parallel lines in the region 460 of the respective photodiode 312.

Vias 424 comprise a conductive inner portion, for example made of heavily-doped silicon of the first conductivity type (N+) or of polysilicon. This inner portion is insulated from region 460 by insulating trenches.

In an example, not shown, the inner portions of two adjacent vias 424 are doped according to an opposite doping type (P+ and N+), so as to form a P-Si/N-QF/N-Si heterojunction with no metal electrode on top.

In the shown example, each channel 604, 606, 608, 610 is insulated from the adjacent channel by an insulator or an insulating trench 620. This insulating trench extends vertically, for example, through filter 304, 306, 308, 310, the photodiode 312 of the respective channel, filter 314, and the photodiode 316 of the respective channel.

In the shown example, regions 439 and vias 424 have a square cross-section, but any other shape can be envisaged.

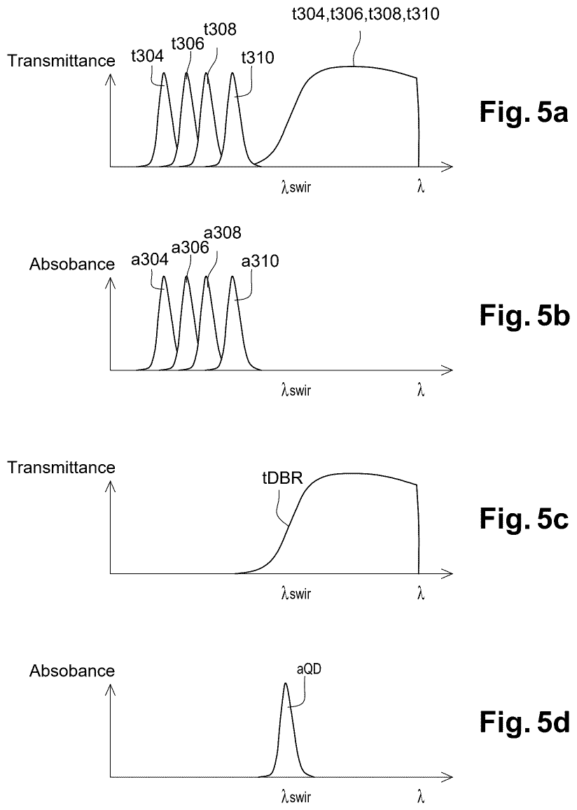

FIG. 5a shows a graph of transmittance versus wavelength for the examples of FIGS. 1 to 3.

In particular, the example of FIG. 5a shows the respective transmittance t304, t306, t308, t310 of filters 304, 306, 308, 310. In this example, filter 304 lets through wavelengths centered around the cyan color, filter 306 lets through wavelengths centered around the green color, filter 308 lets through wavelengths centered around the yellow color, and filter 310 lets through wavelengths centered around the red color. Filters 304, 306, 308 and 310 also let through short-wave infrared wavelengths λswir and higher wavelengths.

FIG. 5b shows a graph of absorbance versus wavelength for the examples of FIGS. 1 to 3. More particularly, FIG. 5b shows the absorbance a304, a306, a308, a310 of the respective photodiode 312 of each channel.

In this example, the photodiode 312 of the respective channel of filter 304 absorbs, a304, wavelengths centered around the cyan color, the photodiode 312 of the respective channel of filter 306 absorbs, a306, wavelengths centered around the green color, the photodiode 312 of the respective channel of filter 308 absorbs, a308, wavelengths centered around the yellow color, and the photodiode 312 of the respective channel of filter 310 absorbs, a310, wavelengths centered around the red color.

The photodiode 312 of each channel lets through short-wave infrared wavelengths λswir and higher wavelengths, which thus become available to the photodiode 316 which is arranged underneath after the passage through filter 314.

FIG. 5c shows a graph of transmittance versus wavelength for the examples of FIGS. 1 to 3. In particular, the example shown in FIG. 5c represents the transmittance tDBR of filter 314.

In the shown example, filter 314 lets through short-infrared wavelengths λswir and higher wavelengths, and absorbs or reflects visible wavelengths. This enables to improve the rejection rate of visible photons for photodiode 316.

FIG. 5d shows a graph of absorbance versus wavelength for the examples of FIGS. 1 to 3. More particularly, FIG. 5d shows the absorbance aQD of the quantum dots of photodiode 316. In this example, the absorbance is centered on short-wave infrared wavelengths λswir, for example 1.130 μm or 1.360 μm, which correspond to excitonic peaks.

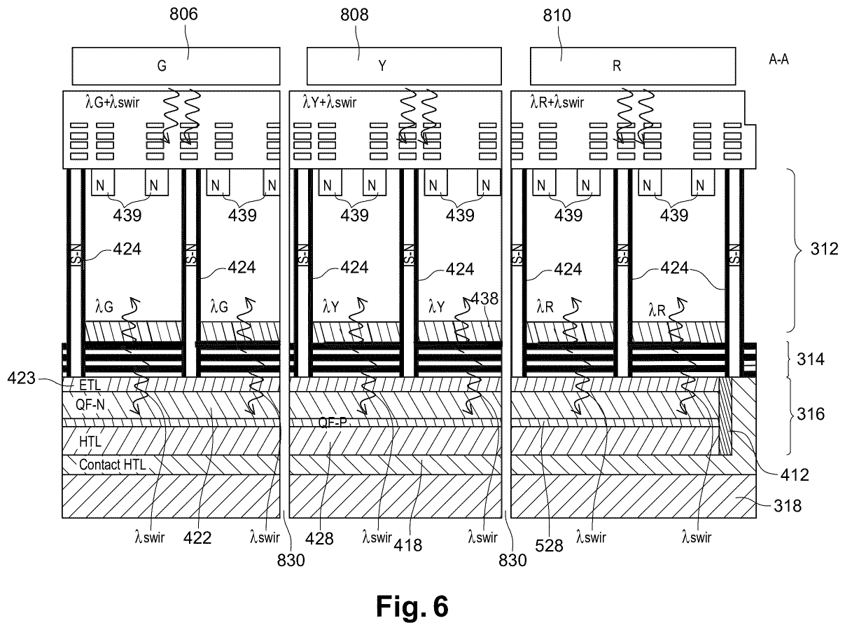

FIG. 6 shows a cross-section view along plane A-A of an example of an electronic device according to another embodiment.

The example of FIG. 6 is similar to that of FIG. 3, with the difference that filters 306, 308, 310 are replaced by interference filters 806, 808, 810. Each of filters 806, 808, 810 only lets through wavelengths of their respective color in the visible range, as well as a narrow band in infrared different for each filter. Thereby, it is possible to form a plurality of channels of different wavelengths in infrared, each channel associated with an infrared frequency band having the same dimensions as the associated channel in the visible range located above it.

In the example of FIG. 6, optional insulating trenches 830 insulate the different channels from one another by insulating filters 806, 808, 810 from one another, the respective interconnection levels, photodiodes 312, photodiodes 316, and insulating layer 318. These trenches 830 may not be necessary, due to the fact that the charge carriers generated in photodiode 316 have a low mobility, and that the application of a vertical electric field is sufficient to prevent crosstalk between channels.

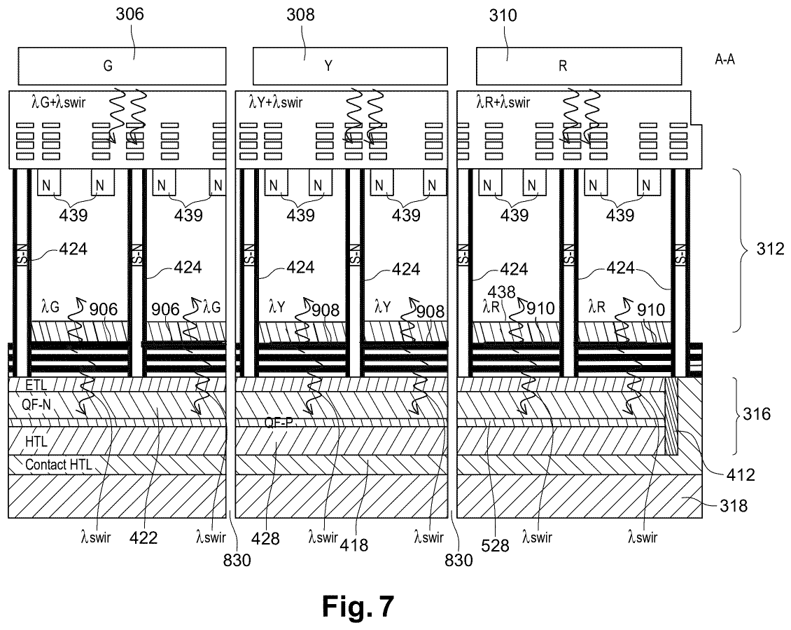

FIG. 7 shows a cross-section view along plane A-A of an example of an electronic device according to another embodiment. In particular, the example of FIG. 7 is similar to that of FIG. 6, except that filters 806, 808, 810 are replaced by filters 306, 308, 310 respectively. Further, in the shown example, filter 314 is replaced, for each of the channels, by an interference filter, or an optical steering element, specific to each channel. For example, the channel associated with filter 306 comprises a filter 906, the channel associated with filter 308 comprises a filter 908, and the channel associated with filter 310 comprises a filter 910. In this example, the transmittance in infrared is different for each of filters 906, 908, and 910. This enables to add channels specifically for the analysis of infrared, for example short-wave.

In an example, to obtain such a transmittance difference between each filter 906, 908, 910, it is sufficient to modify the thickness or the refractive index of the layers periodically repeated in the filters.

In the example of FIG. 7, device 300 may comprise a calculation unit enabling, via a reconstruction matrix, to recalculate the spectrum in short-wave infrared, for example, since a plurality of distinct infrared peaks may be detected by the photodiode 316 of certain channels.

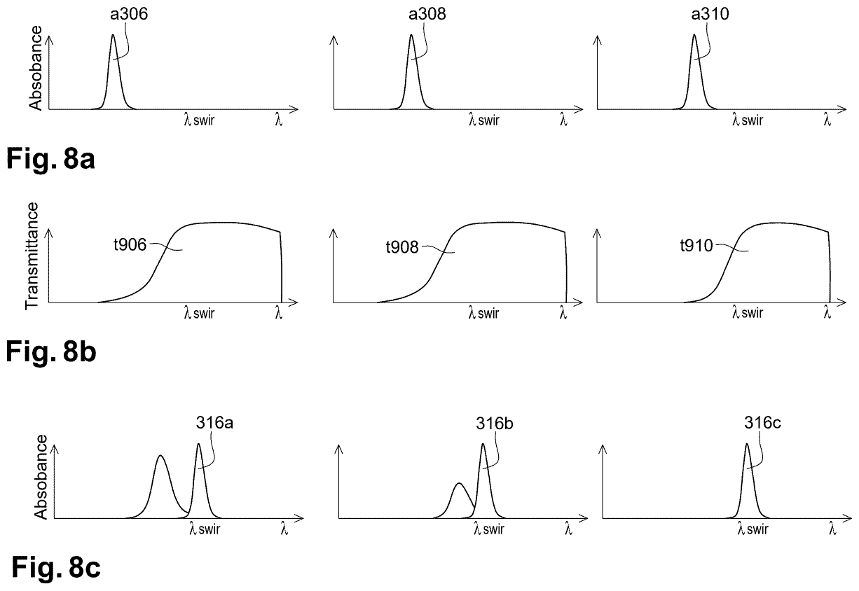

FIG. 8a shows graphs of absorbance versus wavelength for the example of FIG. 7.

In this example, only the absorbance associated respectively with filters 306, 308, 310 is shown for clarity. The photodiode 312 of the respective channel of filter 306 absorbs, a306, wavelengths centered around the green color, the photodiode 312 of the respective channel of filter 308 absorbs, a308, wavelengths centered around the yellow color, and the photodiode 312 of the respective channel of filter 310 absorbs a310 wavelengths centered around the red color.

The photodiode 312 of each channel does not absorb, or only negligibly absorbs, short-wave infrared wavelengths λswir and higher wavelengths, which thus become available to the photodiode 316 which is arranged underneath after passing through the respective filters 906, 908, 910.

FIG. 8b shows graphs of transmittance versus wavelength for the example of FIG. 7. More particularly, FIG. 8b shows the transmittance respectively of filters 906, 908, and 910. In this example, these different filters 906, 908, and 910 have a respective transmittance t906, t908, t910 which is different for infrared, particularly short-wave infrared. For example, filter 906 has a transmittance t906 in short-wave infrared which is higher than that of filter 908, which itself has a transmittance t908 in short-wave infrared which is higher than that t910 of filter 910. Transmittance t910 is almost zero before the excitonic peak of the quantum dots.

FIG. 8c shows graphs of absorbance versus wavelength for the example of FIG. 7.

More particularly, FIG. 8c shows the absorbance 316a, 316b, 316c of the respective photodiode 316 of the channels associated with filters 306, 308, and 310.

In FIG. 8c, absorbance 316a comprises two intensity peaks of the same order of magnitude and respectively centered on the excitonic peak λswir of the quantum dots and on a portion of the infrared spectrum having lengths slightly shorter than the excitonic peak.

In the shown example, absorbance 316b comprises a first intensity peak lower than the excitonic peak centered on the excitonic peak Aswir of the quantum dots. The first peak is on a portion of the infrared spectrum having slightly shorter lengths than the excitonic peak.

In the shown example, absorbance 316c only comprises the excitonic peak λswir of the quantum dots.

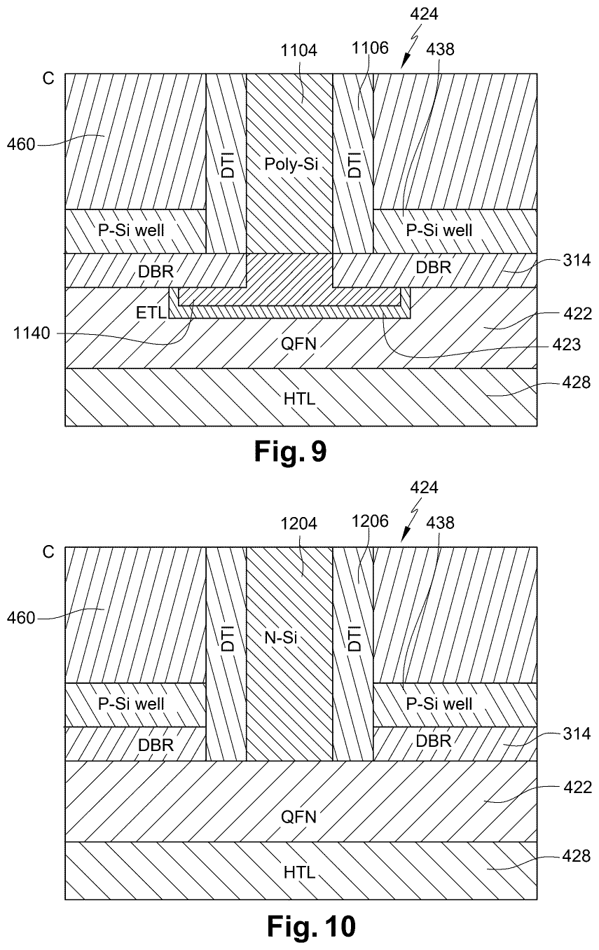

FIG. 9 shows an enlarged view of FIG. 4 according to an embodiment. More particularly, FIG. 9 shows the enlarged view C of the connection between one of vias 424 and the layer 422 of the photodiode 316 of the associated channel.

In the shown example, via 424 comprises a central region, or portion, 1104 made of polysilicon (Poly-Si) within a deep trench isolation 1106. Deep trench isolation trenches 1106 are arranged between region 460, region 438 (P—Si well), region 1104, and have their base in contact with an upper surface of filter 314 so as to electrically insulate via 424 from regions 460 and 438.

In the shown example, the central region 1104 of via 424 is in contact with a portion or region 1140 made of a metallic material having a shallow work function to facilitate electron extraction. In an example, portion 1140 is arranged between portion 1104 and layer 423. Portion 1140 is for example partly arranged between region 1104 and filter 314 (DBR), as well as partly under filter 314 so as to be arranged between layer 423 (ETL) and filter 314.

In an example, region 1140 comprises a plurality of layers of different metallic materials having a low work function.

In the shown example, layer 423 is in contact with region 1140 and is sandwiched between region 1140 and layer 422.

In the example of FIG. 9, vias 424 form deep insulating and capacitive trenches.

The example of FIG. 9 advantageously enables to collect the charges photogenerated close to the collection electrode, and thus to form absorption channels at different wavelengths, as described in FIGS. 6 and 7.

FIG. 10 shows an enlarged view of FIG. 4 according to another embodiment. More particularly, FIG. 10 shows the enlarged view C of the connection between one of vias 424 and the layer 422 of the photodiode 316 of the associated channel.

In the shown example, via 424 comprises a central region, or portion, 1204 made of doped silicon of the first conductivity type, for example N, (N—Si) within a deep trench isolation 1206. Deep trench isolation trenches 1206 are arranged between region 460, region 438 (P—Si well), region 1204, and have their base in contact with a vertical surface of filter 314 so as to electrically insulate via 424 from regions 460 and 438. In this example, the region 1204 of the via 424 of the shown example is in direct contact with layer 422.

In the example of FIG. 10, a heterojunction is thus created between the inner region 1204 of the via and layer 422.

The example of FIG. 10 advantageously enables to simplify the collection of charges by adjusting the silicon doping to remove potential barriers limiting electron extraction, and to reduce the topology associated with the presence of metal electrodes.

The device is, for example, intended for the automotive industry for incident light analysis.

The device is, for example, intended to be used in communications equipment, or in computers and peripherals.

In an example, device 300 is used in LED (Light Emitting Diode) lighting systems to control the light emitted by analyzing incident or emitted light.

Various embodiments and variants have been described. Those skilled in the art will understand that certain features of these various embodiments and variants could be combined, and other variants will become apparent to those skilled in the art. In particular, although examples with a plurality of channels have been disclosed, it is possible for device 300 to contain a single visible channel of one color with one photodiode 312 and one photodiode 316. Further, the use of a filter 314 such as described is not mandatory but preferred to increase the rejection of visible radiation for photodiode 316.

Finally, the practical implementation of the described embodiments and variants is within the abilities of those skilled in the art, based on the functional indications given above. In particular, with regard to the connection between vias 424 and layer 422 in the examples of FIGS. 3, 6, and 7, those skilled in the art may start from the solutions of FIG. 9 or 10 and adapt them to the examples of these drawings so that the inner region of the vias can be coupled or connected to layer 422. As concerns the examples of FIGS. 2, 3, 6, and 7, those skilled in the art will be able to implement these examples with reversed conductivity types by using their knowledge.

1. A device, comprising:
a stack including:
a first silicon photodiode;
a second photodiode based on quantum dots; and
a first filter interposed between the first silicon photodiode and the second photodiode;
wherein the first silicon photodiode is arranged between a side of the stack configured to receive incident light and the first filter; and
wherein the first filter is configured to let infrared wavelengths of the received incident light pass through to the second photodiode and reflect visible wavelengths of the received incident light back to the first silicon photodiode.

2. The device according to claim 1, further comprising a second filter of a first color of the visible range configured to let wavelengths of said first color and infrared wavelengths of the incident light through to the first silicon photodiode.

3. The device according to claim 1, wherein the first silicon photodiode is sensitive only to visible wavelengths of the received incident light.

4. The device according to claim 1, wherein the second photodiode is sensitive mainly to infrared wavelengths of the received incident light.

5. The device according to claim 1, wherein said second photodiode comprises:
a first layer comprising the quantum dots and doped with a first conductivity type; and
a second layer configured to conduct holes originating from the first layer.

6. The device according to claim 5, wherein said second photodiode comprises:
a third layer comprising quantum dots and doped with a second conductivity type;
wherein the third layer is arranged between said first layer and said second layer.

7. The device according to claim 1, further comprising:
a second filter of a first color of the visible range configured to let wavelengths of said first color and infrared wavelengths of the incident light through to the first silicon photodiode; and
an interconnection level comprising conductive interconnects arranged between the first silicon photodiode and the second filter;
wherein a first conductive via, insulated from the first silicon photodiode, couples, through the first silicon photodiode and through the first filter, the second photodiode to the interconnection level.

8. The device according to claim 7, wherein the second photodiode comprises a fourth layer configured to conduct electrons and block conduction of holes, and to couple the first layer to the first conductive via.

9. The device according to claim 8, wherein said first conductive via comprises a first portion made of polysilicon and a second portion of made of a metallic material, said second portion being arranged between the first portion and the fourth layer.

10. The device according to claim 9, wherein said metallic material has a work function facilitating electron extraction.

11. The device according to claim 7, wherein said first conductive via is made of silicon having one of the first or second conductivity type, said first conductive via being in contact with said first layer.

12. The device according to claim 7, wherein the first silicon photodiode comprises a first region doped according to the first conductivity type, a second region doped according to a second conductivity type, and a third region, formed in the first region and doped according to the first conductivity type with a dopant concentration higher than that of the first region, wherein the second region is arranged between the first filter and the first region and the third region is arranged in contact with the interconnection level.

13. The device according to claim 1, wherein said first filter is an interference filter comprising a periodic alternation of an SiON layer of approximately 125 nm thickness and an amorphous silicon layer of approximately 50 nm thickness.

14. The device according to claim 4, comprising:
a further stack including:
a third silicon photodiode;
a fourth photodiode based on quantum dots; and
a third filter interposed between the third silicon first photodiode and the fourth photodiode;
wherein the third silicon photodiode is arranged between a side of the further stack configured to receive incident light and the third interference filter;
wherein the third filter is configured to let infrared wavelengths of the received incident light pass through to the fourth photodiode and reflect visible wavelengths of the received incident light back to the third silicon photodiode;
a second filter of a first color of the visible range configured to let wavelengths of said first color and infrared wavelengths of the incident light through to the first silicon photodiode; and
a fourth filter of a second color of the visible range different from the first color configured to let wavelengths of said second color and infrared wavelengths the incident light through to the third silicon photodiode.

15. The device according to claim 14, wherein the second and fourth filters are interference filters.

16. The device according to claim 15, wherein:
the second filter is configured to let through only wavelengths of said first color and infrared wavelengths to which the second photodiode is sensitive; and
the fourth filter is configured to let through only wavelengths of said second color and infrared wavelengths to which the fourth photodiode is sensitive.

17. The device according to claim 14, wherein the first filter and the third filter are configured to let through different infrared wavelengths.

18. The device according to claim 1, wherein the first silicon photodiode is configured for acquisition of images in visible range and the second photodiode is configured for acquisition of images in infrared range.
